(19) United States
(12) Patent Application Publication
(10) Pub. No.: US 2026/0351291 A1
(43) Pub. Date: Nov. 5, 2026

(54) MRAM DEVICE WITH BOTTOM ELECTRODE

(71) Applicant: Taiwan Semiconductor Manufacturing Company, LTD., Hsinchu (TW)

(72) Inventors: Hai-Dang TRINH, Hsinchu (TW); Yao-Wen CHANG, Taipei (TW); Cheng-Tai HSIAO, Tainan (TW); Ching Ju YANG, Hsinchu (TW); Chia-Hua LIN, New Taipei (TW)

(21) Appl. No.: 19/198,015

(22) Filed: May 3, 2025

(51) Int. Cl. G11C 5/06; H10B 61/00; H10D 64/66; H10N 50/01; H10N 50/10

(52) U.S. Cl. CPC G11C 5/063; H10B 61/22; H10D 64/666; H10N 50/01; H10N 50/10

(57) ABSTRACT

A semiconductor device has at least one memory cell whose bottom electrode is located in a valley formed in the bottom electrode via. The bottom electrode via extends through a primary dielectric layer, and the bottom electrode is located at the same level as the upper surface of the primary dielectric layer. A magnetic tunnel junction (MTJ) is formed upon the bottom electrode, and a top electrode is formed upon the MTJ. The memory cell may be used, for example for magnetic random-access memory (MRAM) in a semiconductor device.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device, such as memory.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a side cross-sectional view of a semiconductor device having one or more memory cells, in accordance with some embodiments of the present disclosure. A magnified view of a magnetic tunnel junction (MTJ) is also included.

FIG. 2A and FIG. 2B together form a flow chart illustrating a first method for making a semiconductor device and/or a memory cell, in accordance with some embodiments.

FIG. 3 is a side cross-sectional view showing some interconnect layers within an interconnect structure, a metal barrier layer, a primary dielectric layer, a hard mask, and a first mask.

FIG. 4 is a side cross-sectional view showing bottom electrode via openings and a barrier layer lining the bottom electrode via openings.

FIG. 5 is a side cross-sectional view after filling the bottom electrode via openings with a metal to form bottom electrode vias.

FIG. 6 is a magnified side cross-sectional view after dishing to form a valley within the bottom electrode via.

FIG. 7 is a side cross-sectional view after filling the valley to form a bottom electrode.

FIG. 8 is a side cross-sectional view after planarization.

FIG. 9 is a side cross-sectional view after application of a magnetic tunnel junction (MTJ) stack, a top electrode layer, a hard mask, and a second mask.

FIG. 10 is a side cross-sectional view after patterning to form a memory cell from the bottom electrode via, the bottom electrode, the MTJ, and the top electrode.

FIG. 11 is a side cross-sectional view after applying a capping layer.

FIG. 12 is a side cross-sectional view after forming an interlayer dielectric (ILD) layer over the capping layer.

FIG. 13 is a perspective view of an array of memory cells which are intersected by an array of bit lines and an array of word lines arranged orthogonally to each other.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” or “over” are used with reference to two different layers (including the substrate), they indicate merely that one layer is on or upon or over the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The term “metal” is used herein to refer to both pure metals and metal alloys. Examples of pure metals may include cobalt, molybdenum, ruthenium, and copper. Examples of metal alloys may include titanium nitride, tantalum nitride, and tungsten nitride.

The present disclosure relates to methods of making memory cells for use in a semiconductor device, and the resulting memory cells and semiconductor devices. In particular, magnetic random-access memory (MRAM) is a form of non-volatile memory (NVM) provides good performance with low power consumption, fast access times, and relatively low degradation over time. An MRAM memory cell includes a magnetic tunnel junction (MTJ), which is formed from two ferromagnetic layers (a free layer and a pinned layer) with a thin insulating layer between them. The MTJ is sandwiched between a bottom electrode and a top electrode. When the MTJ is etched along with the bottom electrode, re-sputter from the bottom electrode may land on the sidewall of the MTJ. This increases process time to clean the MTJ sidewall, and can increase the bit error rate (BER), which is undesirable. In the present disclosure, methods, devices, and systems are disclosed for producing memory cells which reduce re-sputter and desirably reduce the BER.

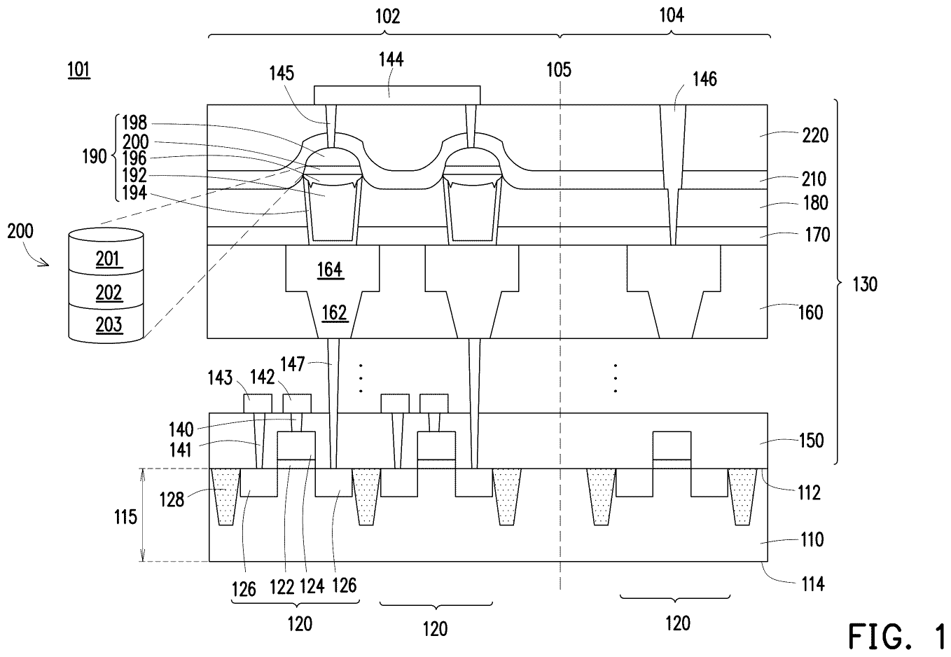

FIG. 1 is a side cross-sectional view of a semiconductor device 101 having one or more memory cells 190, in accordance with some embodiments of the present disclosure. A magnified view of a magnetic tunnel junction (MTJ) 200 is also included.

Initially, the device 101 is divided into a memory region 102 and a logic region 104 as indicated by dashed line 105. Then, starting at the bottom of the device, the semiconductor device includes a substrate 110. Three planar transistors 120 are shown in the substrate. For each transistor, a gate dielectric layer 122 is present upon the substrate 110. A gate electrode 124 is located upon the gate dielectric layer 122. The gate electrode 124 is located between two source/drain (S/D) regions 126 formed within the substrate. The transistors are separated from each other by isolation regions 128, which may be, for example, shallow trench isolation (STI) regions or deep trench isolation (DTI) regions. Although not illustrated, dielectric spacers may be formed upon the substrate around the gate electrode 124 if desired. Two transistors are located in the memory region, and one transistor is located in the logic region. The transistor(s) in the logic region can be used for implementing write/read logic for accessing the memory cells, or perform other functions.

An interconnect structure 130 is then formed upon the substrate 110 above the transistors 120. The interconnect structure permits various components to communicate with each other, and may also be considered a redistribution layer (RDL). The interconnect structure can be formed from one or more combinations of thinner dielectric layers (not shown) and etch stop layers (not shown). Each individual dielectric layer can independently be considered an intermetal dielectric (IMD) layer or an interlayer dielectric (ILD) layer. The dielectric layers include electrically conductive features which are used for communication between various components on the substrate. The interconnect structure may be formed from several dielectric layers, with the conductive features being vertically interconnected by vias 140, 141. As illustrated here, a word line 142 is electrically connected to the gate electrode 124, and a read line 143 (also known as source line) is electrically connected to one S/D region 126.

Continuing, a first interlayer dielectric (ILD) layer 150 and an interconnect layer 160 in the interconnect structure 130 is also illustrated. The interconnect layer 160 is illustrated as including three vias 162 and metal routing 164, which may be an electrically conductive metal such as copper. Two vias are shown in the memory region, and one via is shown in the logic region. The vias 162 in the memory region are also electrically connected to the other S/D region 126 in a transistor below, schematically illustrated here as another via 147. Additional layers in the interconnect structure may be present, and are indicated with the three dots and are not shown here.

A metal barrier layer 170 is present upon, and directly contacts, the interconnect layer 160. A primary dielectric layer 180 is present upon, and directly contacts, the metal barrier layer 170.

Two memory cells 190 are illustrated in the memory region. In each memory cell, a bottom electrode via 192 extends through the primary dielectric layer 180 and the metal barrier layer 170, and is electrically connected to the metal routing 164 and via 162. The bottom electrode via 192 may be lined with a barrier layer 194. A bottom electrode 196 is present upon the bottom electrode via 192. An MTJ 200 is present upon the bottom electrode. A top electrode 198 is present upon the MTJ 200.

In the magnified view, the MTJ is shown as including an upper magnetic layer 201, a lower magnetic layer 203, and a tunnel barrier layer 202 which is made from a thin insulator between the two magnetic layers 201, 203. One of the two magnetic layers is pinned to an antiferromagnetic layer, while the other magnetic layer is a “free” layer whose magnetic field can be changed to store one of two or more corresponding data states.

A capping layer 210 covers the memory cells 190. An interlayer dielectric (ILD) layer 220 covers the capping layer 210. As illustrated here, top vias 145 extend through the ILD layer to the top electrode 198 of each memory cell, and a bit line 144 is electrically connected to the top electrodes 198. A via 146 is also shown in the logic region.

It is noted that all of the layers 150, 160, 170, 180, 210, 220 should be considered part of the interconnect structure 130. Put another way, the memory cells can be considered as being formed within the interconnect structure.

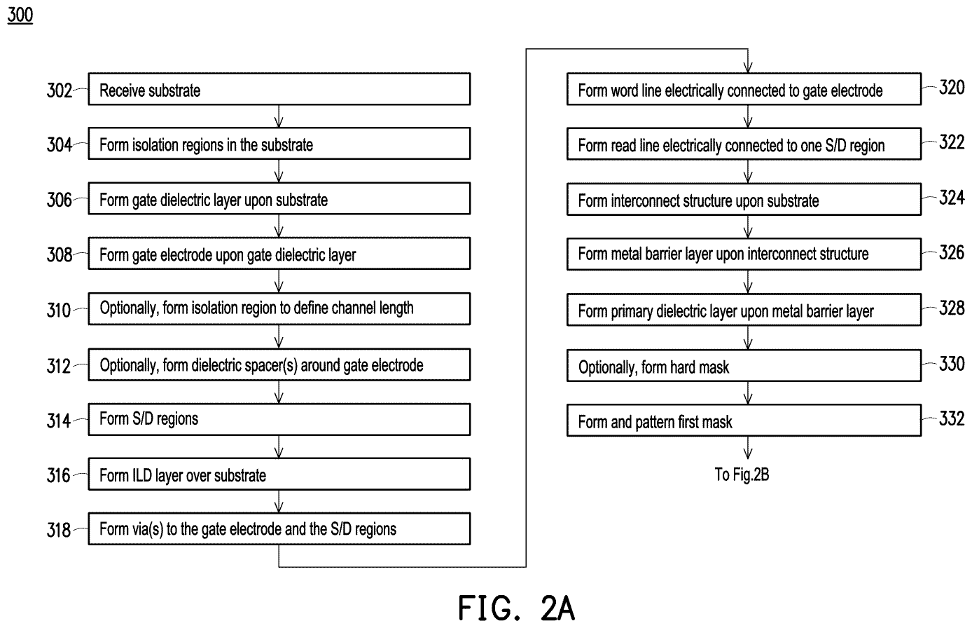

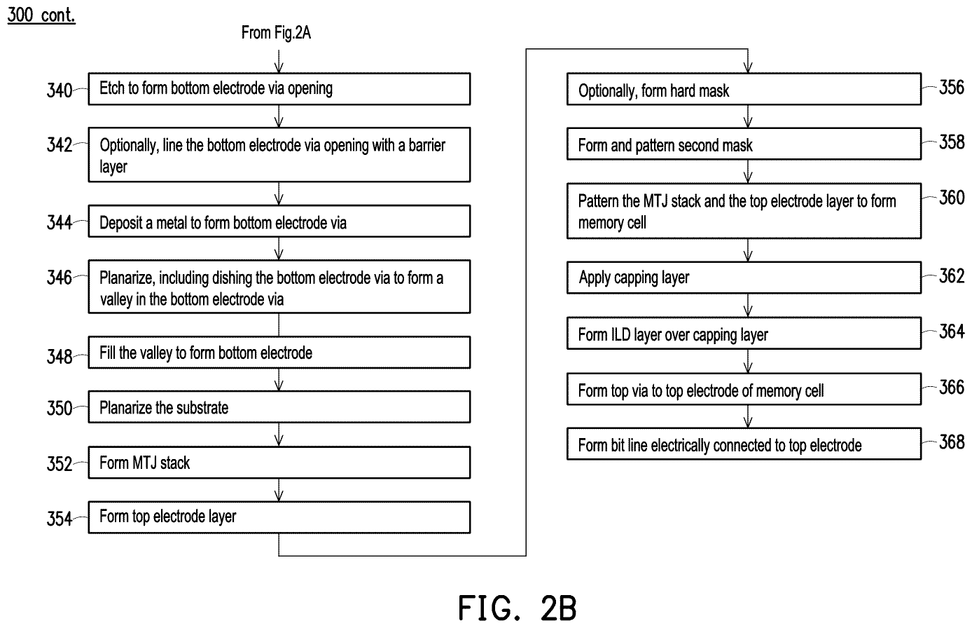

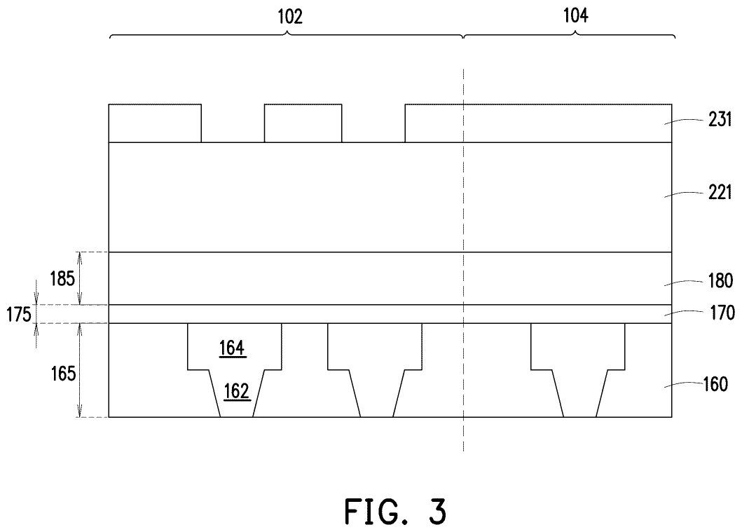

FIG. 2A and FIG. 2B together form a flow chart illustrating a first method 300 for making a semiconductor device 101 and/or a memory cell 190, in accordance with some embodiments. Some steps of the method are also illustrated in FIGS. 3-12. These figures provide different views for better understanding. While the method steps are discussed below in terms of forming a single memory cell, such discussion should also be broadly construed as applying to the concurrent formation of multiple memory cells. The method also describes formation of a planar transistor, but can be suitably adapted to form other transistors or devices. Other structures may also be concurrently formed. It is noted that not all steps described in the flow chart are required, and not all method steps are described in the flow chart.

Initially, referring also to FIG. 1, the method begins at step 302 of FIG. 2A, where a semiconducting substrate 110 is received. Semiconductor materials can include silicon, for example in the form of crystalline Si. In alternative embodiments, the substrate can be made of other elementary semiconductors such as germanium, silicon carbide (SiC), silicon germanium, or silicon germanium carbide. The substrate may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon. The substrate 110 has an upper surface 112 and a lower surface 114, and has a thickness 115 between these two surfaces. The substrate also includes a memory region 102 and a logic region 104.

Then, in step 304 of FIG. 2A, one or more isolation regions 128 are formed in the substrate 100. The isolation regions may be, for example, shallow trench isolation (STI) regions or deep trench isolation (DTI) regions. The isolation regions are formed by patterning the substrate, etching isolation trenches, and filling the trenches with a dielectric material. Deposition of dielectric material can be done using chemical vapor deposition (CVD), physical vapor deposition (PVD), or spin-on processes known in the art, or the dielectric material can be grown via oxidation. If desired, the dielectric material can be deposited to a level above that of the upper surface 112, then recessed back down to the desired height. Each trench extends from the upper surface 112 into the substrate.

Next, in step 306 of FIG. 2A, a gate dielectric layer 122 is formed upon the substrate 110. Again, CVD, PVD, atomic layer deposition (ALD), ion implantation, or other suitable deposition process may be used to form the gate dielectric layer. Thermal oxidation may also be used. The gate dielectric layer 122 is formed between isolation regions 128. Afterwards, in step 308, a gate electrode 124 is formed upon the gate dielectric layer 122. This may be done by CVD, PVD, or other suitable process. The gate electrode may be, for example, a conductive metal or doped polysilicon. Next, in optional step 310 of FIG. 2A, an isolation region (not illustrated) may be formed to one side of the gate electrode to define the channel length. In optional step 312, one or more gate spacers (not illustrated) may be formed upon the sidewalls of the gate electrode 124. The gate spacers can be made from a dielectric material for electrical isolation of the gate electrode. The gate spacer(s) can be made by CVD, PVD, ALD, or other deposition technique.

Then, in step 314 of FIG. 2A, source/drain (S/D) regions 126 are formed on opposite sides of the gate electrode 124. They may be formed using ion implantation or other suitable methods to dope the silicon substrate, or by patterning and deposition of suitable metals. Briefly, in ion implantation, an ion implanter is used to implant atoms into a silicon crystal lattice, modifying the conductivity of the lattice in the implanted location. An ion implanter generally includes an ion source, a beam line, and a process chamber. The ion source produces the desired ions. The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths. Alternatively, the substrate can be partially etched, followed by blanket deposition of the dopant, following by annealing in which the dopant reacts with the underlying exposed silicon.

Common n-type dopants for silicon substrates may include nitrogen (N), phosphorus (P), arsenic (As), bismuth (Bi), or tantalum (Ta). Common p-type dopants for silicon substrates may include boron (B), aluminum (Al), gallium (Ga), or indium (In).

A planar transistor 120 is thus formed. However, it is noted that any transistor may be formed, such as a FinFET or a Gate-All-Around transistor.

Next, in step 316 of FIG. 2A, a first interlayer dielectric (ILD) layer 150 is formed over the substrate and the transistors 120. Then, in step 318, vias 140, 141 are formed to the gate electrode 124 and the two S/D regions 126. In step 320, a word line 142 is formed that is electrically connected to the gate electrode 124. In step 322, a read line 143 is formed that is electrically connected to one of the S/D regions 126 of the transistor 120. The word line and the read line may be formed concurrently. Then, in step 324, an interconnect structure 130 is formed upon the substrate over the transistors. In FIG. 1, all of the layers between the ILD layer 150 and the interconnect layer 160 are formed in this method step, and can be considered to be part of the interconnect structure 130.

Referring now to FIG. 3, the interconnect layer 160 is shown as containing metal routing 164 and vias 162. In step 326 of FIG. 2A, a metal barrier layer 170 is formed upon the interconnect structure, represented here by the interconnect layer 160. This may be done using CVD, PVD, or other suitable deposition processes. The metal barrier layer serves to reduce the migration of metal in the memory cell, and is generally formed from a dielectric material, such as silicon nitride (SiN), silicon carbide (SiC), or silicon carbonitride (SiCN). In particular embodiments, the thickness 165 of the interconnect layer 160 may range from about 1000 angstroms to about 4000 angstroms. In particular embodiments, the thickness 175 of the metal barrier layer 170 may range from about 100 angstroms to about 400 angstroms. Other ranges and values for each of these measurements are also within the scope of the disclosure.

Then, in step 328 of FIG. 2A, a primary dielectric layer 180 is formed upon the metal barrier layer 170. This may be done using CVD, PVD, or other suitable deposition processes. In particular embodiments, the primary dielectric layer is formed from a silicon oxide, such as silicon dioxide. In particular embodiments, the thickness 185 of the primary dielectric layer 180 may range from about 300 angstroms to about 2000 angstroms. Other ranges and values for each of these measurements are also within the scope of the disclosure.

The bottom electrode via is then formed. In optional step 330 of FIG. 2A, a hard mask 221 is applied over the primary dielectric layer 180. Then, in step 332 of FIG. 2A, a first mask 231 (e.g. photoresist) is formed and patterned. The resulting structure is shown in FIG. 3. As can be seen here, the area over the metal vias 162 is exposed in the memory region 102.

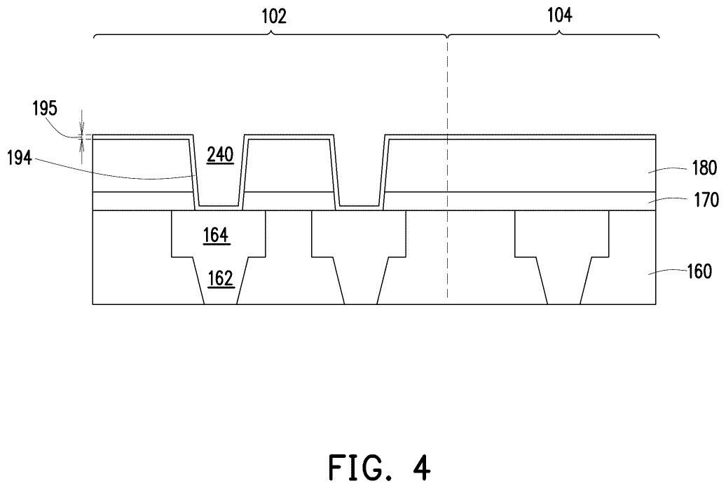

Next, in step 340 of FIG. 2B and as illustrated in FIG. 4, etching is performed to form a bottom electrode via opening 240. The bottom electrode via opening extends through the primary dielectric layer 180 and the metal barrier layer 170 to the interconnect layer 160. Thus, an electrical connection is formed. The hard mask and the first mask are then removed. If desired, in optional step 342 of FIG. 2B, the bottom electrode via opening may be lined with a barrier layer 194. The barrier layer may be formed using ALD, PVD, or other suitable deposition processes. This barrier layer is also intended to reduce metal migration. The barrier layer is formed from an electrically conductive material, such as titanium, tantalum, titanium nitride (TiN), or tantalum nitride (TaN). In particular embodiments, the thickness 195 of the barrier layer 194 may range from about 10 angstroms to about 200 angstroms. Other ranges and values for each of these measurements are also within the scope of the disclosure. The resulting structure is shown in FIG. 4, with the barrier layer 194 covering both the memory region 102 and the logic region 104.

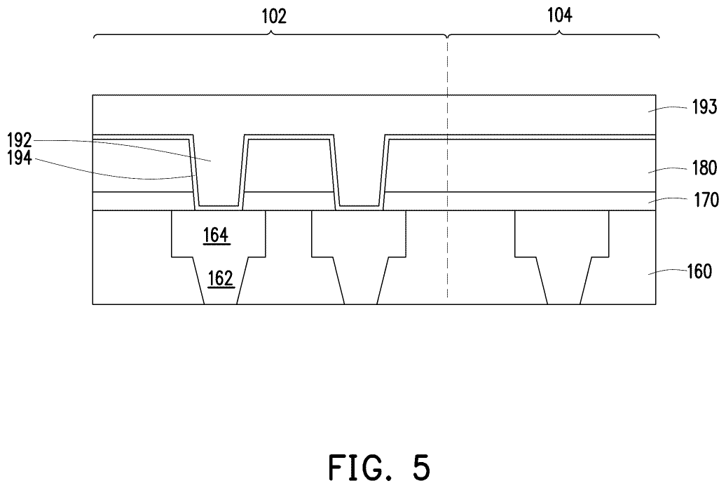

Continuing, in step 344 of FIG. 2B and as illustrated in FIG. 5, a metal is deposited that fills the bottom electrode via opening to obtain a bottom electrode via 192. The metal may be, for example, tungsten (W), titanium (Ti), tantalum (Ta), ruthenium (Ru), titanium nitride (TiN), or tantalum nitride (TaN). The metal may be deposited using any suitable process such as CVD, PVD, sputtering, etc. As illustrated here, a metal layer 193 is also formed over the barrier layer 194.

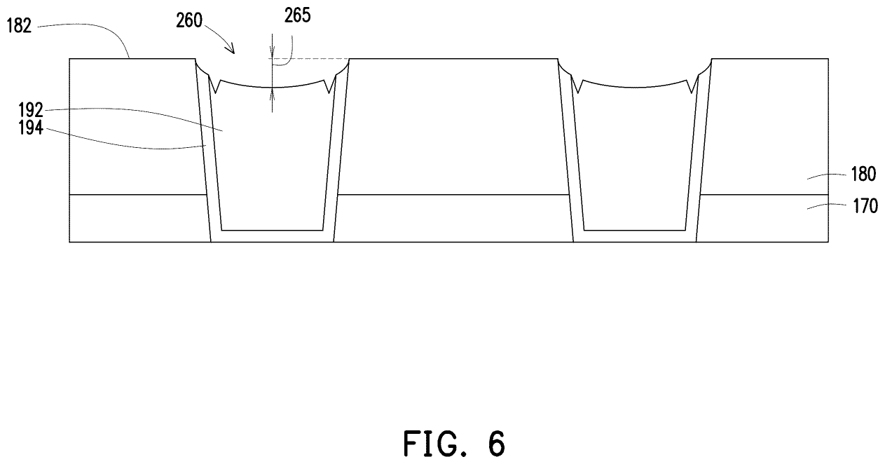

Then, in step 346 of FIG. 2B and as illustrated in FIG. 6, the surface of the substrate is planarized to remove excess material. Planarization of a surface may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the surface. During polishing, both the polishing pad and the carrier rotate, and this induces mechanical and chemical effects on the top layer, removing undesired materials and creating a highly level surface. A post-CMP cleaning step is then carried out using rotating scrubber brushes along with a washing fluid to clean one or both sides of the wafer substrate.

In particular, as illustrated here in FIG. 6, the slurry may be selected so as to cause dishing of the bottom electrode via. Dishing occurs when the slurry is selected to have a higher removal rate for the metal relative to the dielectric material. As a result, a valley 260 is created in the bottom electrode via. The depth 265 of the valley is measured at the lowest point in the valley relative to the upper surface 182 of the primary dielectric layer 180. In particular embodiments, the depth 265 of the valley may range from about 0.5 nanometers (nm) to about 2 nanometers. Other ranges and values for each of these measurements are also within the scope of the disclosure.

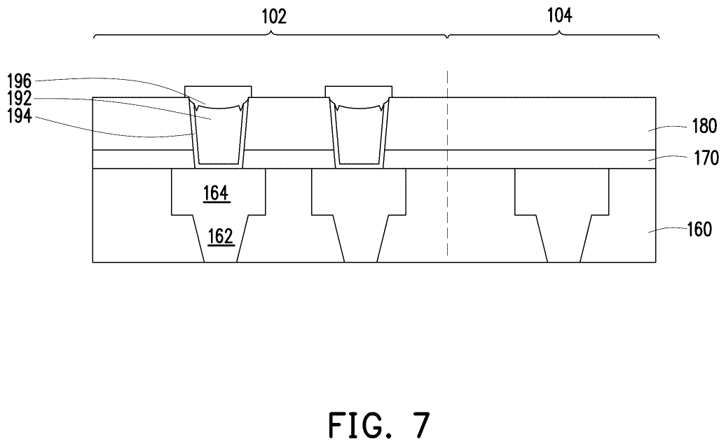

Then, in step 348 of FIG. 2B and as illustrated in FIG. 7, a metal is deposited to fill the valley 260 and form a bottom electrode 196. The metal may be, for example, cobalt (Co), molybdenum (Mo), tungsten (W), ruthenium (Ru), copper (Cu), tantalum nitride (TaN), titanium nitride (TiN), or tungsten nitride (WN). The metal may be deposited using any suitable process such as CVD, PVD, sputtering, etc. If desired, a mask may be applied to control the location of the metal deposition.

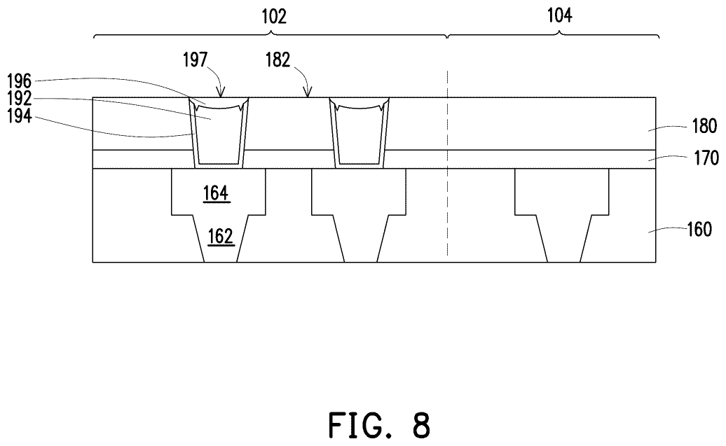

Subsequently, in step 350 of FIG. 2B and as illustrated in FIG. 8, the substrate is planarized again. As a result, the top surface 197 of the bottom electrode 196 is substantially level with the upper surface 182 of the primary dielectric layer 180.

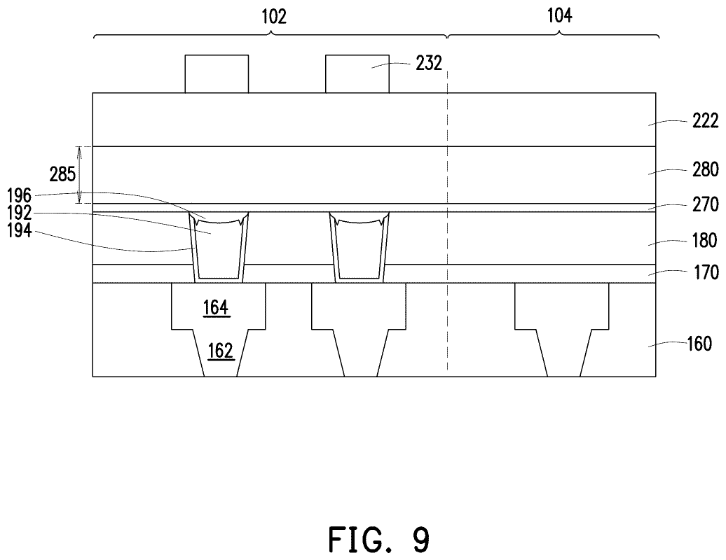

Next, in step 352 of FIG. 2B and as illustrated in FIG. 9, an MTJ stack 270 is formed over the primary dielectric layer 180. The MTJ stack includes a lower magnetic layer, a tunnel barrier layer, and an upper magnetic layer (not separately shown). Then, in step 354, a top electrode layer 280 is formed over the MTJ stack 270. The top electrode layer may be made of any suitable material, such as those previously described for the bottom electrode. In particular embodiments, the thickness 285 of the top electrode layer 280 and the resultant top electrode may range from about 100 angstroms to about 1000 angstroms. Other ranges and values for each of these measurements are also within the scope of the disclosure.

If desired, in optional step 356 of FIG. 2B, a hard mask 222 is deposited. These layers may be formed by any suitable deposition process. Then, in step 358, a second mask 232 (e.g. photoresist) is formed and patterned. The resulting structure is illustrated in FIG. 9. The second mask exposes the areas around the bottom electrode.

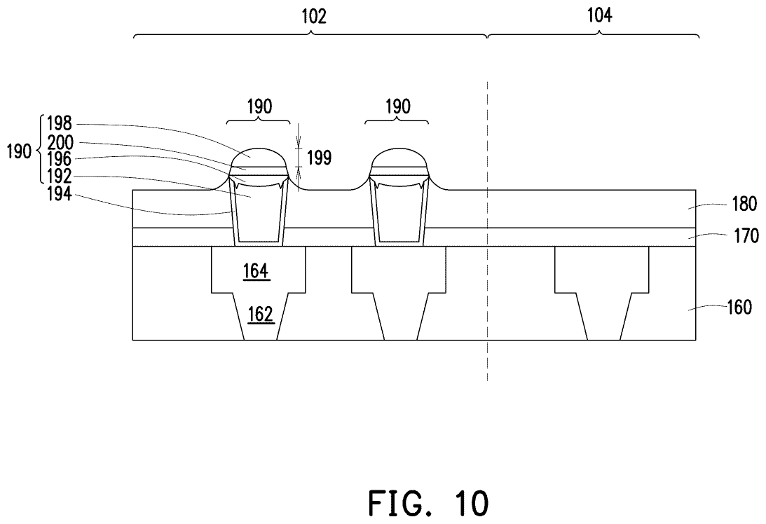

Then, in step 360 of FIG. 2B and as illustrated in FIG. 10, the MTJ stack and the top electrode layer are patterned. This is typically done by etching. As a result, the MTJ 200 and top electrode 198 are formed. In particular embodiments, the thickness 199 of the top electrode may range from about 100 angstroms to about 1000 angstroms. Other ranges and values for each of these measurements are also within the scope of the disclosure.

A memory cell 190 is thus formed, which includes the bottom electrode via 192 the bottom electrode 196, the MTJ 200, and the top electrode 198. As illustrated in FIG. 10, the etching may extend into the primary dielectric layer 180. The hard mask and the second mask are then removed. Two memory cells 190 are illustrated in the memory region 102.

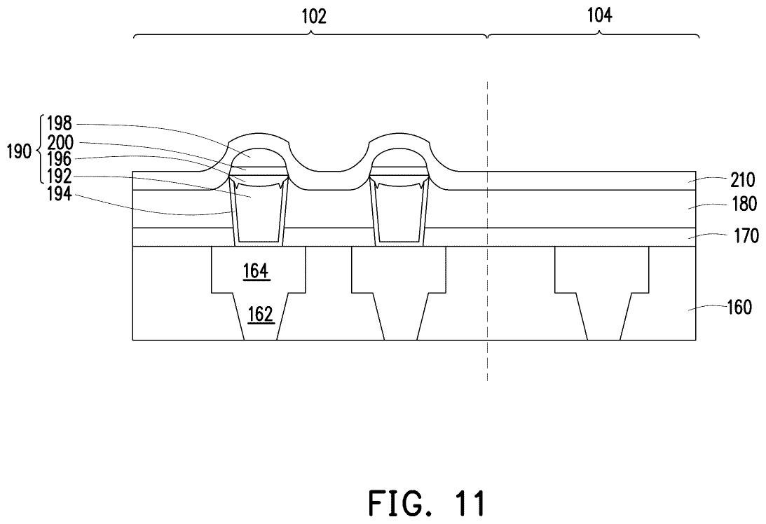

Continuing, in step 362 of FIG. 2B and as illustrated in FIG. 11, a capping layer 210 is applied over the memory cells 190 and the primary dielectric layer 180. The capping layer may be any suitable dielectric material, for example a silicon oxide (SiO), silicon nitride (SiN), silicon oxynitride (SiON), silicon carbide (SiC), or silicon carbonitride (SiCN). In particular embodiments, the thickness 215 of the capping layer 210 may range from about 50 angstroms to about 1000 angstroms. Other ranges and values for each of these measurements are also within the scope of the disclosure. The capping layer is illustrated as a film, and may be applied using ALD or other suitable deposition process. The capping layer aids in passivating the exposed sidewalls of the memory cell.

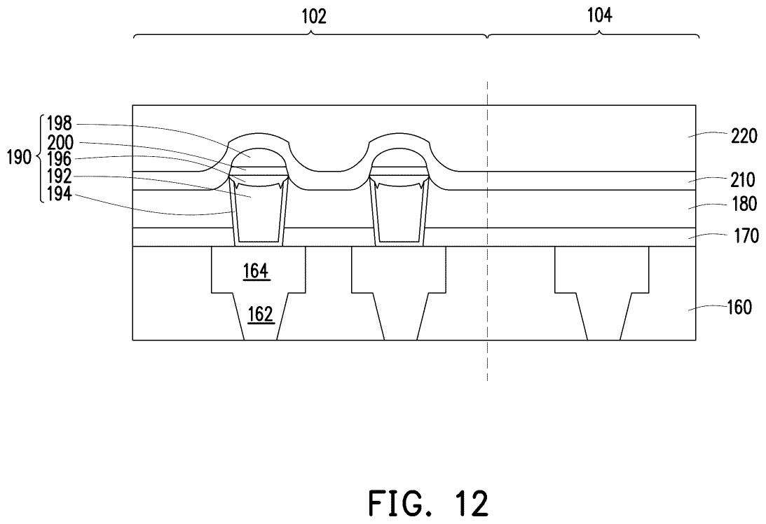

Next, in step 364 of FIG. 2B and as illustrated in FIG. 12, an ILD layer 220 is applied over the capping layer. The ILD layer may be any suitable dielectric material, and may be applied using CVD, PVD, or other suitable deposition process.

Subsequently, in step 366 of FIG. 2B and referring back to FIG. 1, a top via 145 is formed to the top electrode 198 of each memory cell. Finally, in step 368 of FIG. 2B, a bit line 144 is formed which is electrically connected to the top electrode 198 of a memory cell. The word line 142, read line 143, and bit line 144 are used to read/write the memory cell. It is noted they do not have to be in the locations described herein. For example, the word line and the read line could be above the memory cell.

As illustrated in FIG. 1, each memory cell 190 is electrically connected to one transistor 120. This may be referred to as a 1T1M structure (i.e. 1 transistor 1 memory cell). Other structures, such as 3T2M, 2T2M, or 2T1M, are also within the scope of the present disclosure.

Many dielectric layers are described herein. Non-limiting examples of electrically insulating materials (i.e. dielectric materials) which can be used in the present disclosure may include oxides such as silicon dioxide (SiO₂), aluminum oxide (Al₂O₃), tantalum oxide (Ta₂O₅), zirconium dioxide (ZrO₂), or hafnium dioxide (HfO₂); nitrides such as silicon carbon nitride (SiCN), silicon nitride (SiN), hafnium oxynitride (HfOₓN_{y}), zor irconium oxynitride (ZrOₓN_{y}), where 0<x, y, ≤1; silicates like hafnium silicates (HfSiₓO_{y}) or zirconium silicates (ZrSiₓO_{y}), where 0<x, y, ≤1; polysilicon, phosphosilicate glass (PSG), fluorosilicate glass (FSG), undoped silicate glass (USG), high-stress undoped silicate glass (HSUSG), borosilicate glass (BSG), a high-k dielectric material, or a low-k dielectric material.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

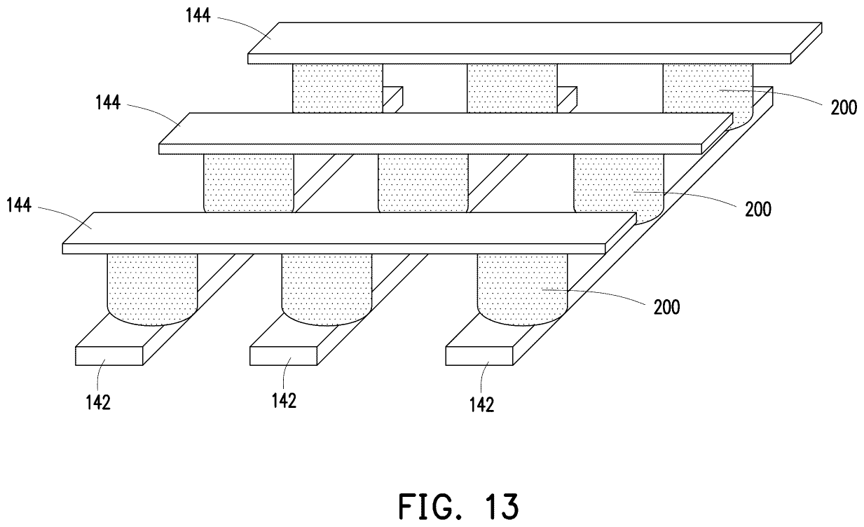

FIG. 13 illustrates an example array of MRAM memory cells arranged into row and columns. The MRAM cells in the same row are connected to a common word line, and the MRAM cells in the same column are connected to a common bit line. Here, nine MTJs 200, three word lines 142, and three bit lines 144 are shown, with other components removed for ease of illustration. They are arranged orthogonally to each other. Any number of MRAM cells may be arranged in such an array.

The MTJ 200 uses tunnel magnetoresistance (TMR) to store magnetic fields. Data may be written to each memory cell in many ways. In one method, current is passed between the two magnetic layers 201, 203, which induces a magnetic field stored in the free magnetic layer. In another method, spin-transfer-torque (STT) is used, wherein a spin-aligned or polarized electron flow changes the magnetic field within the free magnetic layer with respect to the pinned magnetic layer. This may be done, for example, by current or electron flow through the bit line or the word line. Other methods to write data may be used. However, all writing methods include changing the magnetic field within the free magnetic layer with respect to the pinned magnetic layer.

The electrical resistance of the MTJ 200 changes in accordance with the magnetic fields stored in the two magnetic layers 201, 203. For example, when the magnetic fields of the two magnetic layers are aligned, the MTJ has a relatively low resistance, which can represent a “0” state. When the magnetic fields of the two magnetic layers are oppositely aligned, the MTJ has a relatively high resistance, which can represent a “1” state. By measuring the electrical resistance between the two magnetic layers, read circuitry can determine whether the memory cell is in the “0” or “1” state.

Semiconductor devices containing the memory cells illustrated herein may be used in any application and/or device that uses memory. Such devices might include central processing units (CPUs), graphics processing units (GPUs), graphics integrated circuits, server or power management integrated circuits, and image signal processors (ISP). Other devices might include LCD, OLED, AMOLED, or QLED display panels; cameras; hard drives; computers including laptops, desktops, tablets, etc. ; mobile telephones; media players, smart watches, gaming consoles; routers, servers, etc.

The memory cells of the present disclosure have several advantages. Because the bottom electrode is formed prior to formation of the MTJ and the top electrode, re-sputter does not occur, and so the time/cost to remove the re-sputtered material from the MTJ can be avoided. In addition, the amount of metal being etched is reduced, which also reduces processing time, improving throughput and yield.

Some embodiments of the present disclosure thus relate to methods for forming a memory cell. A bottom electrode via opening is formed in a primary dielectric layer in a memory region. The bottom electrode via opening is filled to form a bottom electrode via. Dishing is performed on the bottom electrode via to form a valley below an upper surface of the primary dielectric layer. The valley is filled with a metal to form a bottom electrode. A magnetic tunnel junction (MTJ) stack and a top electrode layer are formed over the bottom electrode. The MTJ stack and the top electrode layer are then patterned to form the memory cell having an MTJ and a top electrode.

Other embodiments disclosed herein relate to memory cells. The memory cell comprises a bottom electrode via extending through a primary dielectric layer. A bottom electrode is formed in a valley in the bottom electrode via below an upper surface of the primary dielectric layer. A magnetic tunnel junction is located upon the bottom electrode, and a top electrode is located upon the magnetic tunnel junction.

Also described in various embodiments herein are semiconductor devices, comprising a substrate, a first transistor upon the substrate, and an interconnect structure upon the substrate above the transistor. A metal barrier layer is located upon the interconnect structure, and a primary dielectric layer is located upon the metal barrier layer. A memory cell is electrically connected to a first source/drain region of the first transistor. The memory cell comprises a bottom electrode via; a bottom electrode formed in a valley of the bottom electrode via below an upper surface of the primary dielectric layer; a magnetic tunnel junction upon the bottom electrode; and a top electrode upon the magnetic tunnel junction.

The present disclosure also relates in various embodiments to devices that use such memory cells, to methods of using such memory cells to store data, and to methods of reading such memory cells, and writing such memory cells.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a memory cell in a semiconductor device, comprising:
forming a bottom electrode via opening in a primary dielectric layer in a memory region of the semiconductor device;
filling the bottom electrode via opening to form a bottom electrode via;
dishing the bottom electrode via to form a valley below an upper surface of the primary dielectric layer;
filling the valley with a metal to form a bottom electrode;
forming a magnetic tunnel junction (MTJ) stack and a top electrode layer over the bottom electrode; and
patterning the MTJ stack and the top electrode layer to form the memory cell having an MTJ and a top electrode.

2. The method of claim 1, wherein the valley has a depth of about 0.5 nanometers to about 2 nanometers.

3. The method of claim 1, wherein the metal used to form the bottom electrode comprises Co, Mo, W, Ru, Cu, TaN, TiN, or WN.

4. The method of claim 1, wherein the bottom electrode via opening is filled with a metal comprising W, Ru, Ti, Ta, TiN, or TaN.

5. The method of claim 1, further comprising lining the bottom electrode via opening with a barrier layer before filling the bottom electrode via opening.

6. The method of claim 5, wherein the barrier layer comprises Ti, Ta, TiN, or TaN.

7. The method of claim 1, wherein the bottom electrode via opening extends through the primary dielectric layer and a metal barrier layer to an interconnect layer.

8. The method of claim 7, wherein the metal barrier layer comprises a dielectric material.

9. The method of claim 1, further comprising planarizing the substrate before forming the MTJ stack and the top electrode layer.

10. The method of claim 1, further comprising:
applying a capping layer over the memory region;
forming an interlayer dielectric (ILD) layer over the capping layer;
forming a top via to the top electrode; and
forming a bit line electrically connected to the top via.

11. The method of claim 10, wherein the capping layer is formed from a dielectric material.

12. The method of claim 1, wherein the bottom electrode via is electrically connected to a source/drain region of a transistor.

13. A memory cell in a semiconductor device, comprising:
a bottom electrode via extending through a primary dielectric layer;
a bottom electrode formed in a valley in the bottom electrode via below an upper surface of the primary dielectric layer;
a magnetic tunnel junction upon the bottom electrode; and
a top electrode upon the magnetic tunnel junction.

14. The memory cell of claim 13, wherein the valley has a depth of about 0.5 nanometers to about 2 nanometers.

15. The memory cell of claim 13, wherein the bottom electrode does not extend above the upper surface of the primary dielectric layer.

16. The memory cell of claim 13, further comprising a barrier liner around the bottom electrode via.

17. The memory cell of claim 13, further comprising a metal barrier layer below the primary dielectric layer, wherein the bottom electrode via also extends through the metal barrier layer.

18. The memory cell of claim 13, wherein the bottom electrode is electrically connected to a source/drain region of a transistor and the top electrode is electrically connected to a bit line.

19. A semiconductor device, comprising:
a substrate;
a first transistor upon the substrate;
an interconnect structure upon the substrate above the transistor;
a metal barrier layer upon the interconnect structure;
a primary dielectric layer upon the metal barrier layer; and
a memory cell electrically connected to a first source/drain region of the first transistor, the memory cell comprising:
a bottom electrode via;
a bottom electrode formed in a valley of the bottom electrode via below an upper surface of the primary dielectric layer;
a magnetic tunnel junction upon the bottom electrode; and
a top electrode upon the magnetic tunnel junction.

20. The device of claim 19, further comprising:
a word line electrically connected to a gate electrode of the first transistor; and
a read line electrically connected to a second source/drain region of the first transistor.
